(19) United States
(12) Patent Application Publication
(10) Pub. No.: US 2021/0201474 A1
(43) Pub. Date: Jul. 1, 2021

(54) SYSTEM AND METHOD FOR PERFORMING VISUAL INSPECTION USING SYNTHETICALLY GENERATED IMAGES

(71) Applicant: Photogauge, Inc., Belmont, CA (US)

(72) Inventors: Sameer SHARMA, Alamo, CA (US); Vishwanath VENKATARAMAN, Alamo, CA (US); Rohit MALIK, Alamo, CA (US); Yousaf BILAL, Alamo, CA (US); Sankara J. SUBRAMANIAN, Alamo, CA (US)

(21) Appl. No.: 17/203,957

(22) Filed: Mar. 17, 2021

Related U.S. Application Data
(63) Continuation-in-part of application No. 17/128,141, filed on Dec. 20, 2020.
Application No. 17/128,141 is a continuation of application No. 16/023,449, filed on Jun. 29, 2018, now Pat. No. 10,885,622.
Application No. 16/023,449 is a continuation-in-part of application No. 16/131,456, filed on Sep. 14, 2018.
Application No. 16/131,456 is a continuation-in-part of application No. 16/023,449, filed on Jun. 29, 2018, now Pat. No. 10,885,622.

(51) Int. Cl. G06T 7/00; G06T 7/30; G06K 9/00; G06F 30/17

(52) U.S. Cl. CPC G06T 7/0004; G06F 30/17; G06K 9/00671; G06T 7/30

(57) ABSTRACT

A system and method for performing visual inspection using synthetically generated images is disclosed. An example embodiment is configured to: receive one or more images of a compliant manufactured component; receive images of component defects; use the images of component defects to produce a variety of different synthetically-generated images of defects; combine the synthetically-generated images of defects with the one or more images of the compliant manufactured component to produce synthetically-generated images of a non-compliant manufactured component; and collect the one or more images of the compliant manufactured component with the synthetically-generated images of the non-compliant manufactured component into a training dataset to train a machine learning system.

### PRIORITY PATENT APPLICATIONS

This is a continuation-in-part (CIP) patent application claiming priority to U.S. non-provisional patent application Ser. No. 17/128,141, filed on Dec. 20, 2020; which is a continuation application of patent application Ser. No. 16/023,449, filed on Jun. 29, 2018. This is also a CIP patent application claiming priority to U.S. non-provisional patent application Ser. No. 16/131,456, filed on Sep. 14, 2018; which is a CIP of patent application Ser. No. 16/023,449, filed on Jun. 29, 2018. This present patent application draws priority from the referenced patent applications. The entire disclosure of the referenced patent applications is considered part of the disclosure of the present application and is hereby incorporated by reference herein in its entirety.

### COPYRIGHT

A portion of the disclosure of this patent document contains material that is subject to copyright protection. The copyright owner has no objection to the facsimile reproduction of the patent document or the patent disclosure, as it appears in the Patent and Trademark Office patent files or records, but otherwise reserves all copyright rights whatsoever. The following notice applies to the disclosure provided herein and to the drawings that form a part of this document: Copyright 2018-2021 PhotoGAUGE, Inc., All Rights Reserved.

### TECHNICAL FIELD

This patent application relates to computer-implemented software systems, metrology systems, photogrammetry-based systems, and automatic visual measurement or inspection systems, and systems for quality control of manufactured or naturally occurring materials, components, or assemblies according to example embodiments, and more specifically to a system and method for performing visual inspection using synthetically generated images.

### BACKGROUND

Visual inspection is an essential step in the quality assurance (QA) process of fabricated components or objects. For example, visual inspection is performed for: 1) recognizing cracks, scratches, discolorations and other blemishes on manufactured parts, gemstone, floor tile, leather sheet surfaces, etc., 2) assessing the integrity of a component assembly by identifying misassembled or missing subcomponents; 3) measuring the size, position, surface roughness, etc. of objects or features on an object; and 4) counting the number of objects or features, such as holes and slots, on a component or object.

Visual inspection is commonly performed manually. However, repetitive manual inspection by human inspectors is subjective, error-prone (affected by inspector fatigue), and expensive. Therefore, there are on-going efforts to automate visual inspection. In the past, automated visual inspection used a form of inflexible machine vision algorithms. More recently, automated visual inspection has used machine learning models, which can continuously learn and adapt to more dynamic inspection scenarios, such as variable location, size and shape of defects, variety of parts to be inspected, and the like.

Typically, a machine learning model is trained to learn representations of good and/or defective components using a supervised strategy. The supervised strategy trains the model by inputting into the model a large quantity of labelled training examples of good and/or defective components. These training examples can include a large set of photographs, three-dimensional (3D) point clouds, range data, or other types of representations of both good and/or defective components. Depending on the problem space, these training datasets may contain just a few to millions of labelled training examples.

However, collecting and labelling such large training datasets is not always feasible or possible. Firstly, labelling training examples of good and/or defective components is a manual process. Therefore, labelling a large training dataset containing millions of images is a tedious, expensive, and sometimes impossible task. Equally importantly, depending on the scrap rate for a component, it may take months, if not years, to collect sufficient numbers of component samples with the desired kinds of defects required to train the machine learning model to the desired level of accuracy. Lastly, the required number of units of a certain component may never be produced in reality since the demand may be very small, e.g. in typical ‘high-mix, low-volume’ production.

Thus, although sophisticated mathematical processes and machine learning models may be available to solve a given problem, a solution may never be developed because of the lack of training data needed to train the machine learning models to the desired level of accuracy.

### SUMMARY

In various example embodiments described herein, a system and method for performing visual inspection using synthetically generated images are disclosed. In the various example embodiments described herein, a synthetic training data generation system is provided to address the shortcomings of the conventional technologies as described above. The synthetic training data generation system of various example embodiments disclosed herein can be configured to generate synthetic training data for training a machine learning model used in many different component manufacturing or inspection applications including: 1) component assembly verification, 2) component defect detection, and 3) component and component feature count detection.

The various example embodiments described herein provide a system and method to use synthetically or virtually generated images, point clouds, range images, etc. for training machine learning models to analyze components or objects, thereby eliminating or drastically reducing the number of physical samples or images of actual samples of components or objects required for training the machine learning model. Because such synthetic training data are generated programmatically on a computer, there is no limit to the number of training images that can be generated for training a machine learning model. Therefore, the various example embodiments described herein can particularly address component or object inspection problems where the paucity of real objects or their images prevents traditional machine learning solutions. Details of the various example embodiments are provided below.

### BRIEF DESCRIPTION OF THE DRAWINGS

The various embodiments are illustrated by way of example, and not by way of limitation, in the figures of the accompanying drawings in which:

FIGS. 1 through 6 illustrate sample images showing an example component assembly or fixture rendered with synthetically generated backgrounds, lighting conditions, and camera angles;

FIGS. 7 through 9 illustrate sample images showing results obtained for real images processed by a machine learning model trained using synthetic image data according to an example embodiment;

FIG. 10 illustrates sample images showing a representative component (e.g., a pinion gear) that needs to be checked for defects, wherein an acceptable “good” flank surface of the sample component is shown and a “defective” flank surface with a large pit in the sample component is shown;

FIG. 11 illustrates sample images showing various types of defective flank surfaces on a component, wherein image portions of the various defects are extracted and synthetically added to a good surface of the component to produce synthetic images of the component with defects of different sizes, orientations, locations, and quantities;

FIG. 12 illustrates a sample image showing a representative component (e.g., a sheet metal plate) with hundreds of holes or features, which need to be counted using a machine learning model;

FIGS. 13 and 14 illustrate sample images showing a representative component (e.g., a sheet metal plate) with hundreds of holes or features, which need to be counted (FIG. 13), and the results of a feature detector implemented as a machine learning model trained to identify and count holes or features of a component according to an example embodiment;

FIGS. 15 and 16 are structure diagrams that illustrate example embodiments of systems as described herein;

FIG. 17 is a processing flow diagram that illustrates example embodiments of methods as described herein; and

FIG. 18 shows a diagrammatic representation of a machine in the example form of a computer system within which a set of instructions when executed may cause the machine to perform any one or more of the methodologies discussed herein.

### DETAILED DESCRIPTION

In the following description, for purposes of explanation, numerous specific details are set forth in order to provide a thorough understanding of the various embodiments. It will be evident, however, to one of ordinary skill in the art that the various embodiments may be practiced without these specific details.

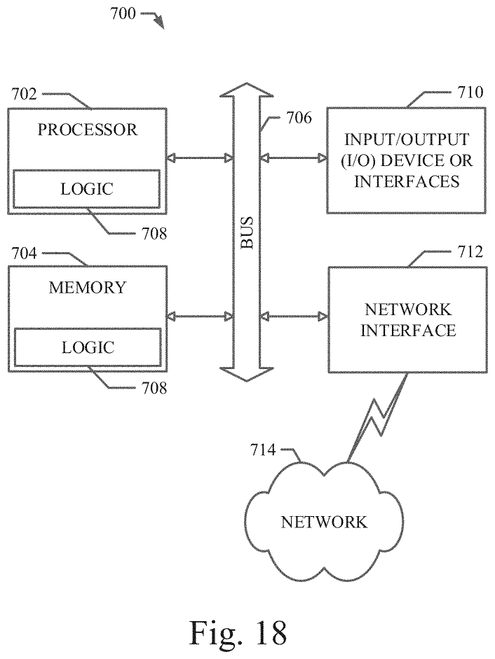

In various example embodiments described herein, a system and method for performing visual inspection using synthetically generated images are disclosed. In the various example embodiments described herein, a synthetic training data generation system can be implemented on or with a computing platform, such as the computing platform described below in connection with FIG. 18. Additionally, the synthetic training data generation system of an example embodiment can be implemented with an imaging system or perception data capture capability to capture images of components or objects being analyzed. However, an imaging system or perception data capture capability is not a required part of the synthetic training data generation system as the synthetic training data generation system can use images or perception data of components or objects being analyzed that can be captured independently or separately from the synthetic training data generation system.

In the various example embodiments described herein, the synthetic training data generation system can be configured to generate synthetic training data for training a machine learning model used in many different component manufacturing or inspection applications including: 1) component assembly verification, 2) component defect detection, and 3) component and component feature count detection. Example embodiments of the synthetic training data generation system configured for each of these different component manufacturing or inspection applications are described below.

### Component Assembly Verification

In a typical manufacturing environment, a component manufacturer needs to verify that all sub-components of a component assembly have been assembled correctly. The challenges here include: 1) the presence of many sub-components, each with numerous variations leading to a few thousand different variants of the final component assembly; 2) the production of only a small quantity (e.g., 10-15 units) of each variant of the component assembly, such as when they are requested by a customer, and 3) the need of a verification system that will be able to detect bad or non-compliant component assemblies for all the different variants of the final component assembly prior to even a single unit being physically assembled. Thus, component manufacturers are faced with a situation where there is a large variety of component assembly variants that need to be verified, but only a few, if any, physical units may be produced. Because there are so few physical units available, there is not a sufficient quantity of physical components from which machine learning model training images can be obtained. Without a sufficient quantity and variety of training images, the machine learning model cannot be properly trained and the visual inspection of component assemblies cannot be automated.

The various example embodiments described herein provide a convenient way to solve this problem by generating synthetic machine learning training images using a 3D engine as part of the synthetic training data generation system. Inside this engine, computer-aided design (CAD) models for the different sub-components of the component assembly can be virtually assembled and rendered into the various component assembly variants. Then, these various component assembly variants can be rendered under a variety of different lighting conditions, various camera settings or angles, different virtual backgrounds, and the like. In this manner, virtually-generated component assembly variants can be rendered under a variety of conditions and poses. Any number of images of the component assembly variants can be generated. These images of the component assembly variants representing synthetic machine learning training images can be used to train a machine learning system to recognize compliant and non-compliant component assemblies.

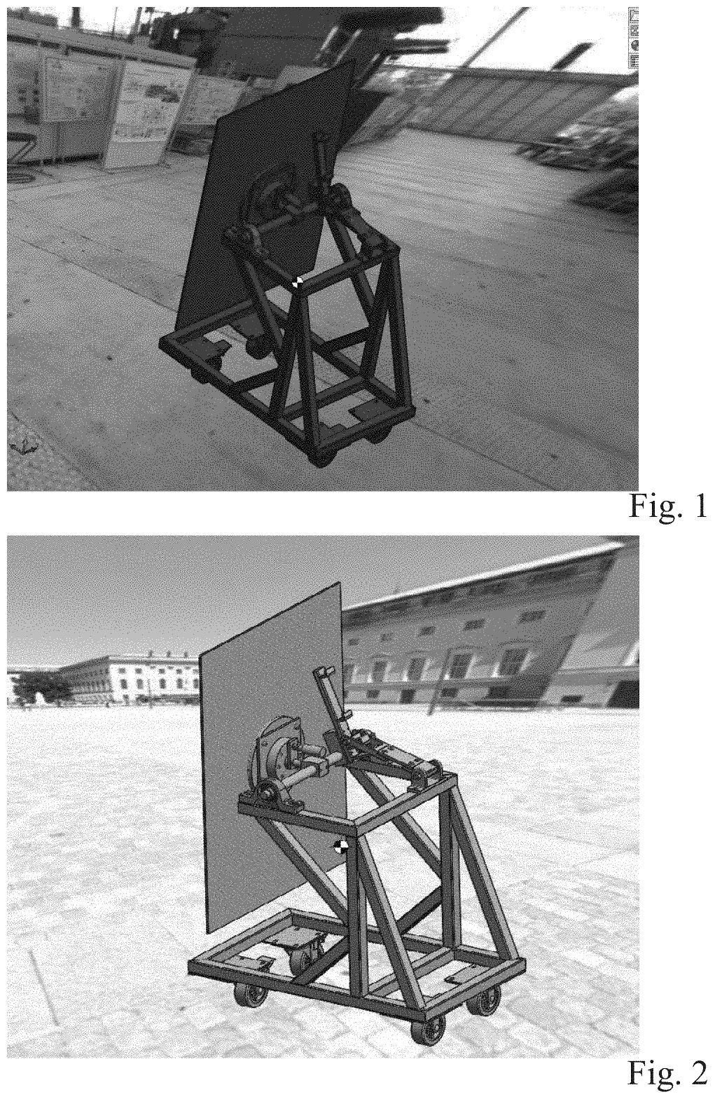

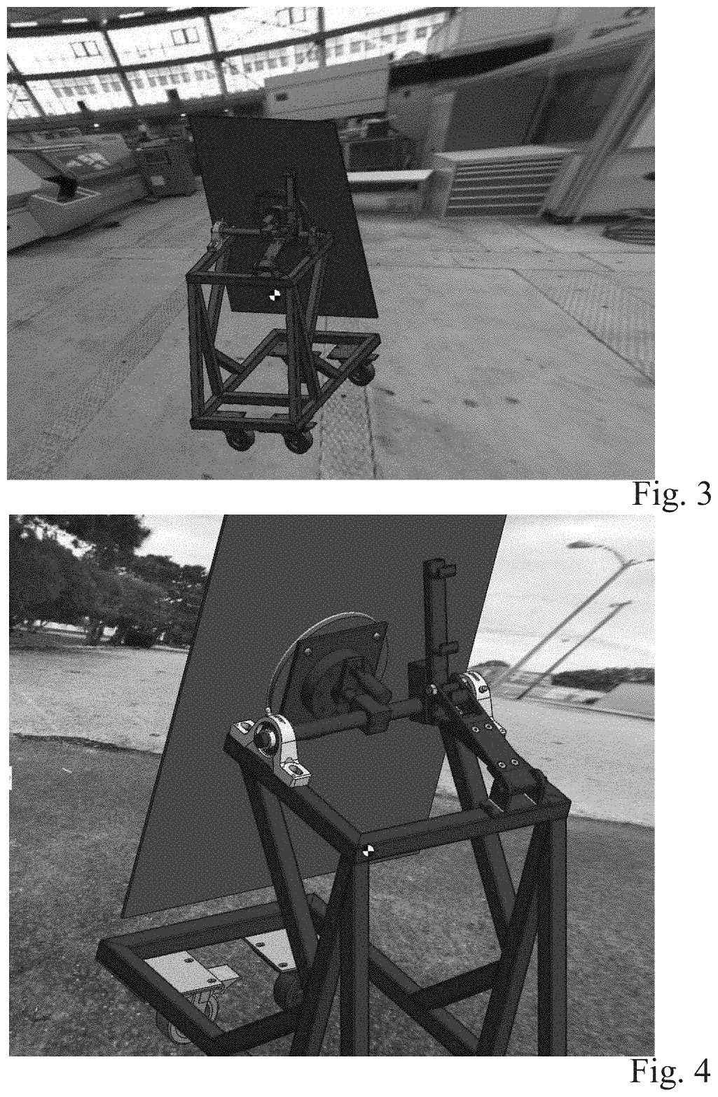

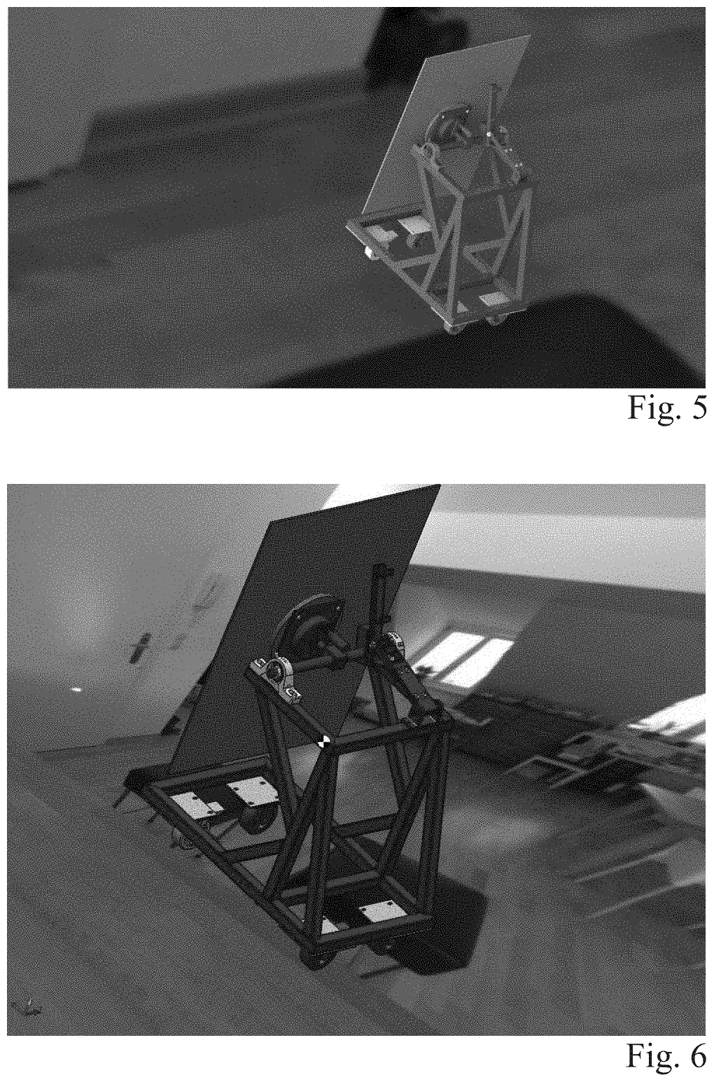

FIGS. 1 through 6 show examples of a few of these virtually-generated component assembly variants. Referring now to FIGS. 1 through 6, sample images illustrate an example component assembly or fixture rendered with synthetically generated backgrounds, lighting conditions, and camera angles. Any number of variations of the synthetically or virtually-generated images can be rendered in this fashion. Particularly relevant backgrounds, lighting, or poses can also be used to configure the synthetic machine learning training images for a particular environment or application.

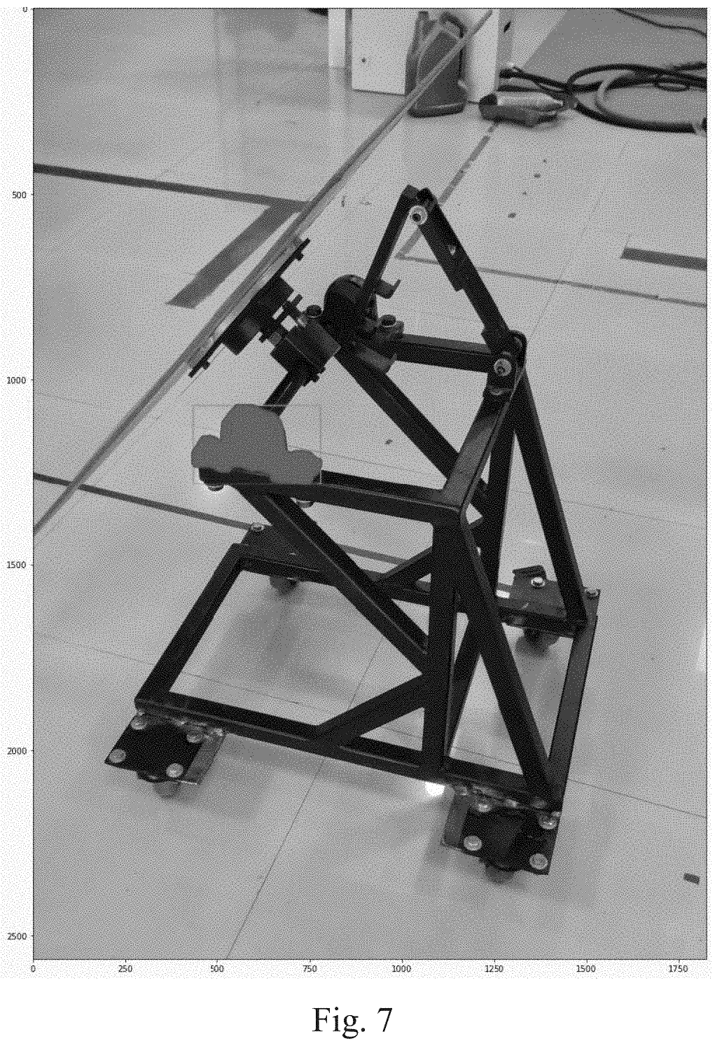

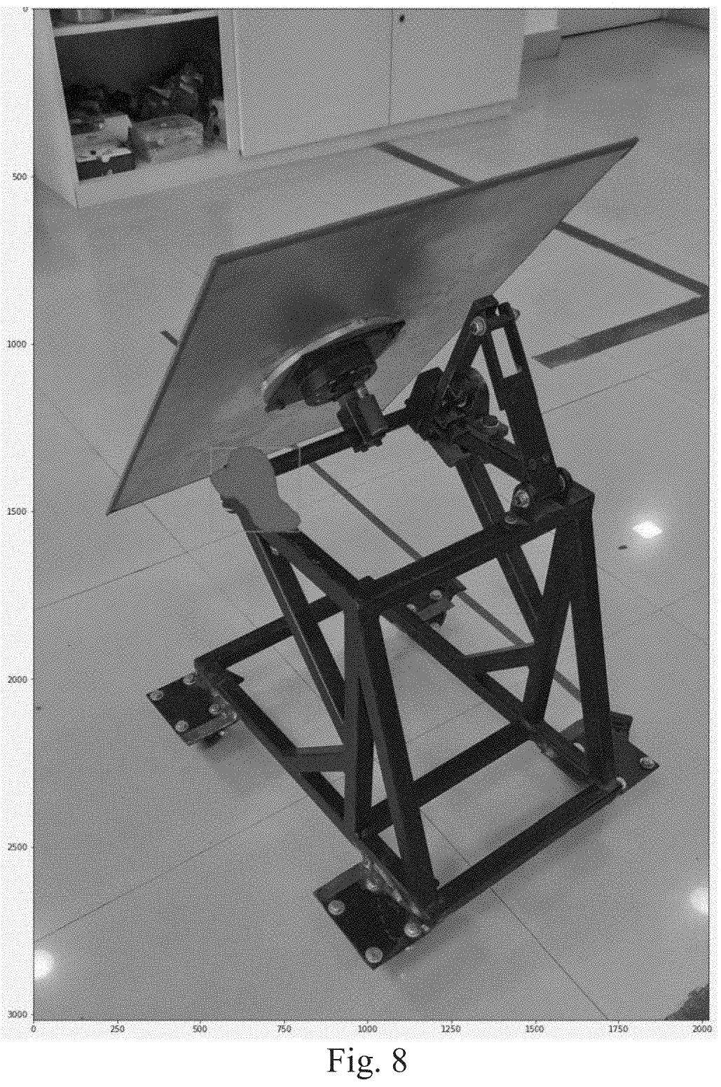

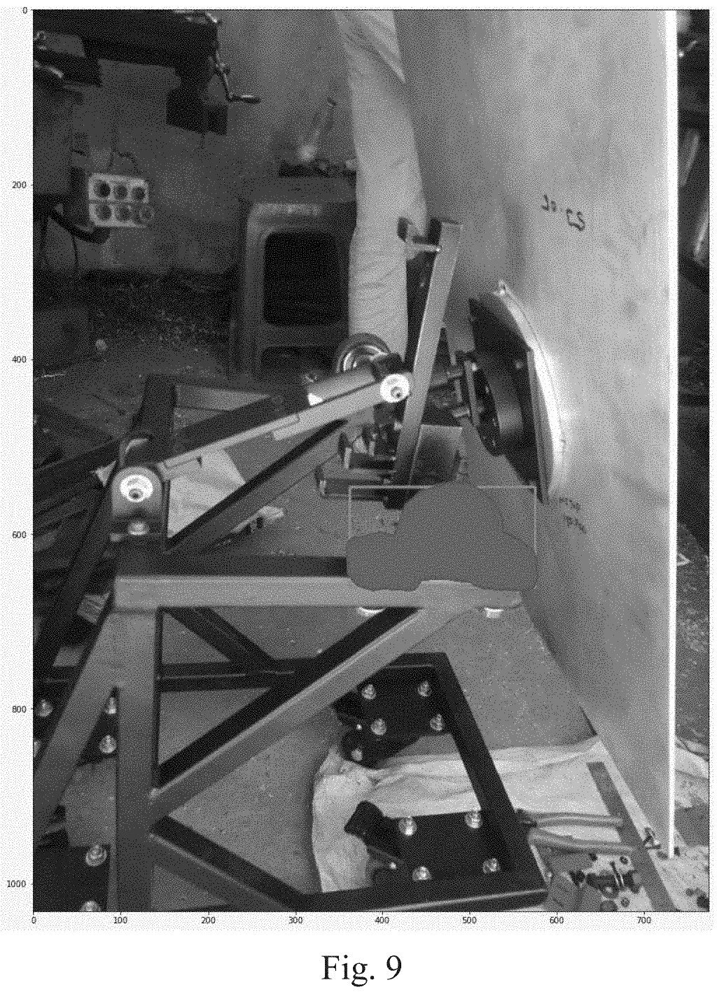

These synthetically or virtually-generated training images can then be used to train a machine learning system, which can then detect each sub-component of the component assembly based on the variations presented by the synthetic machine learning training images. The machine learning system can also classify each detected sub-component into its particular variant based on the variations presented by the synthetic machine learning training images. In this manner, the machine learning system can be trained by the synthetically-generated training images to detect the presence or absence of one or more sub-components of a component assembly. The proper configuration of the component assembly can verified by checking the results of the machine learning system against the expected or desired results for a particular component assembly. The results of the machine learning system can be visually rendered as an image of the component assembly with bounding boxes or color variations identifying particular sub-components detected (or missing) as part of a component assembly. An outcome showing different bounding boxes drawn by a machine learning system trained using the synthetic machine learning training images of an example embodiment is shown in FIGS. 7 through 9.

FIGS. 7 through 9 illustrate sample images showing results obtained for real images processed by a machine learning system trained using synthetic image data generated according to an example embodiment. As shown, the trained machine learning system has detected a sub-component of the sample component assembly as shown by the bounding boxes and color variations. These results are made possible by synthetically-generated training images produced in the manner described above and used to train the machine learning system.

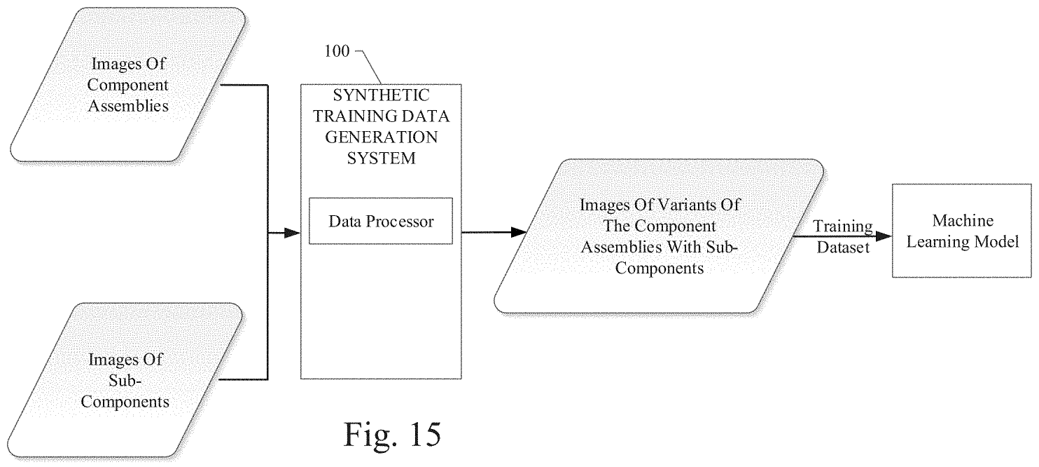

Referring now to FIG. 15, a structure diagram illustrates example embodiments of systems as described herein. The synthetic training data generation system 100 of an example embodiment can be configured as a software application executable by a data processor. The data processor can include an image receiver to receive a source of images of assemblies of manufactured components. The data processor and image receiver can also be in data communication with a source of images of sub-components of the component assemblies. As described above, the synthetic training data generation system 100 of an example embodiment can be configured to virtually assemble models for different sub-components of the component assembly and render the sub-component models into images of various component assembly variants. Each component assembly variant can represent a different sub-component configuration and/or a different view or pose of the component assembly. Images of these variants of the component assemblies with sub-component configurations can be collected into a training dataset and used to train a machine learning system. The trained machine learning system can be used to identify a compliant or non-compliant component assembly with sub-components.

### Component Defect Detection

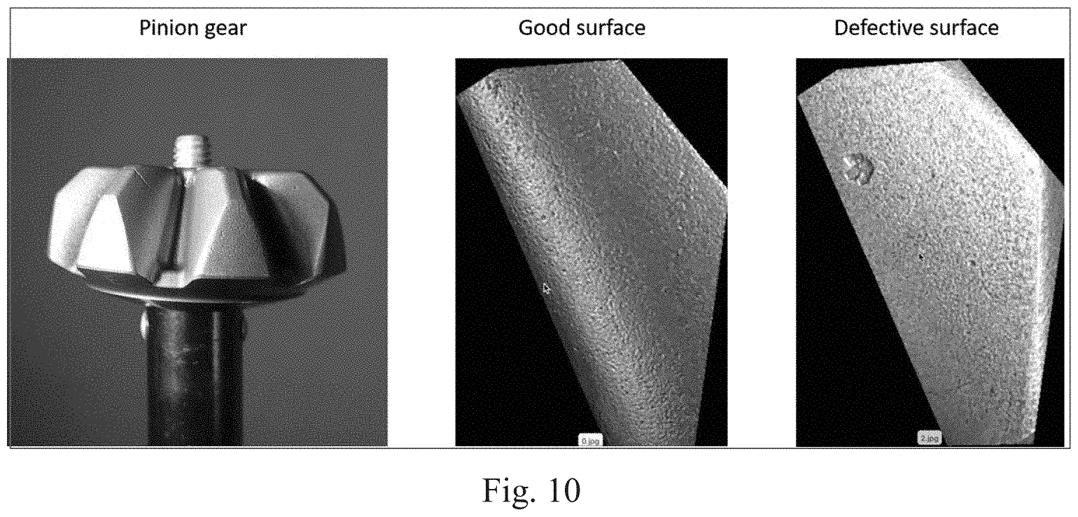

In a typical manufacturing environment, a component manufacturer needs to be able to identify defective components, including components having various abnormalities such as cracks, dents, foreign material, etc. An example manufactured component is shown in FIG. 10. Referring to FIG. 10, sample images illustrate a representative component (e.g., a pinion gear) that needs to be checked for defects, wherein an acceptable “good” flank surface of the sample component is shown and a “defective” flank surface with a large pit in the sample component is shown. In some cases, conventional component manufacturers use trained machine learning models to assist in the detection of these component defects. However, these machine learning models are typically trained with actual images of defective physical components. The difficulty in using the conventional approach of collecting actual images of defective physical components for use as training data is that it takes a long time to collect a sufficiently large set of images of defective components that represents the variety of component defects and the variability in the sizes, orientations, and locations of the defects on the components. As a result, the conventional machine learning models are not sufficiently trained with a robust set of defective component images, which results in an inefficient trained machine learning model.

The various example embodiments described herein provide a convenient way to solve this problem by generating synthetic machine learning training images using the 3D engine as part of the synthetic training data generation system. Inside this engine, a computer-aided design (CAD) system can render a 3D virtual model of a particular manufactured component. Then, the virtual model of the component can be rendered under a variety of different lighting conditions, various camera settings or angles, different virtual backgrounds, and the like. Additionally, the virtual model of the component can be rendered with a variety of different surface textures. The texture information for a particular manufactured component can be obtained from a small set of actual images of the physical manufactured component. In most cases, an acceptable surface texture of a particular manufactured component has natural variability. The synthetic training data generation system of an example embodiment can use the CAD system to generate a 3D virtual model of a particular manufactured component with a desired structure and surface texture (e.g., a good or compliant component) in a variety of different lighting conditions, various camera settings or angles, different virtual backgrounds. This 3D virtual model of a particular manufactured component can be used to represent a variety of good or compliant components. In this manner, a virtually-generated 3D model of a compliant component can be rendered under a variety of conditions and poses. Any number of images of the compliant components can be generated.

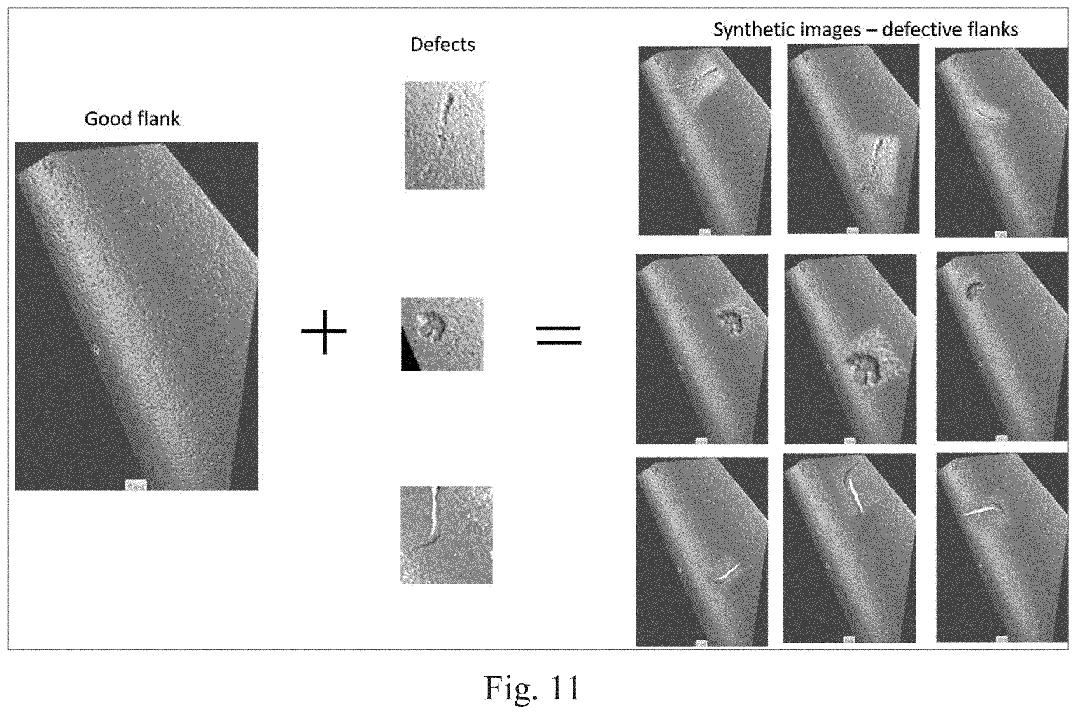

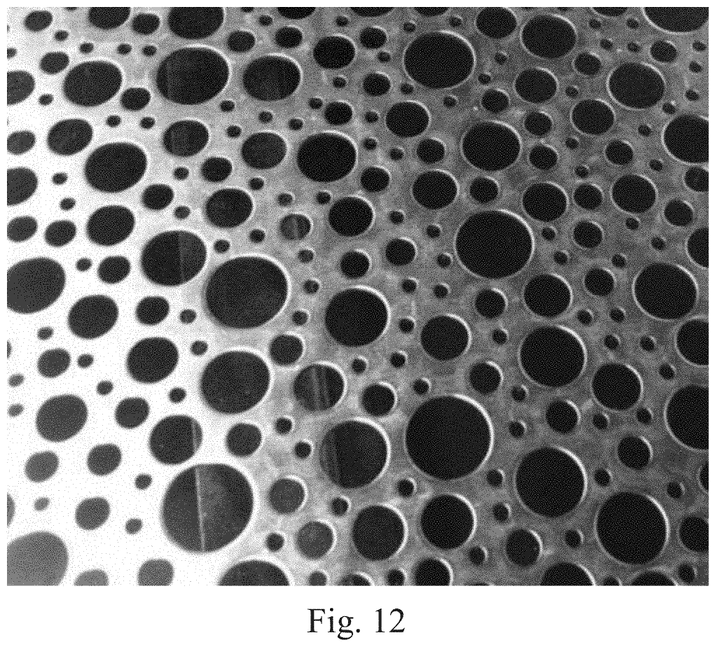

Similarly, images of various types of component defects and their variations can be obtained from selected images of previously manufactured components. Once the visual structure of these defects is abstracted from these selected images, the visual structure of these component defects can be virtually simulated or extracted and added into images of the compliant components. In this manner, virtual defects can be added to images of compliant components to produce synthetically or virtually-generated images of non-compliant components. One advantage of this approach is that the visual structure of component defects can be obtained from a small number of images of defective physical components. These sample images of component defects can be used to produce a variety of different synthetically or virtually-generated images of defects, wherein the defects can be varied in size, orientation, location, quantity, and the like. This variety of different synthetically or virtually-generated images of defects can be added to images of the compliant components to produce a variety of different images of defective or non-compliant components. A large variety and quantity of these different images of defective or non-compliant components can be synthetically generated in this manner. This large set of different synthetically generated images of defective or non-compliant components can be used as a training dataset to train a machine learning system to detect compliant and non-compliant manufactured components. A sample manufactured component processed by the synthetic training data generation system of an example embodiment is shown in FIG. 11.

FIG. 11 illustrates sample images showing various types of defective flank surfaces on a sample manufactured component, wherein image portions of the various defects are extracted and synthetically added to an image of a good surface of the manufactured component to produce synthetic images of the component with defects of different sizes, orientations, locations, and quantities. As shown, in FIG. 11, a variety of different images of component defects can be synthetically or virtually combined with or used to augment or modify images of a portion of a component to synthetically render the component as a defective component, even though a physical component may not have the same defect. As shown in FIG. 11, the images of component defects can be re-sized, rotated, re-located, multiplied, or the like prior to being synthetically or virtually combined with or used to augment or modify images of a portion of a component. In this manner, a large quantity of different variations of a defect on a component can be synthetically generated. This large set of different synthetically generated images of defective or non-compliant components can be used as a training dataset to train a machine learning system to detect compliant and non-compliant manufactured components.

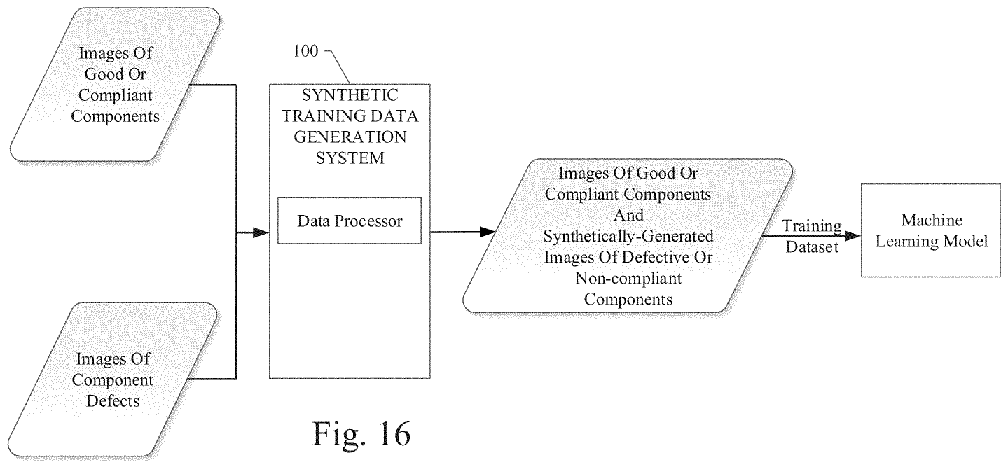

Referring now to FIG. 16, a structure diagram illustrates example embodiments of systems as described herein. The synthetic training data generation system 100 of an example embodiment can be configured as a software application executable by a data processor. The data processor can include an image receiver to receive a source of images of good or compliant manufactured components. The data processor and image receiver can also be in data communication with a source of images of component defects. As described above, the synthetic training data generation system 100 of an example embodiment can be configured to use these images of component defects to produce a variety of different synthetically or virtually-generated images of defects, wherein the defects can be varied in size, orientation, location, quantity, and the like. This variety of different synthetically or virtually-generated images of defects can be added, merged, or otherwise combined into images of the compliant components to produce a variety of different images of defective or non-compliant components. A large variety and quantity of these different images of compliant components and defective or non-compliant components can be synthetically generated in this manner. This large set of different synthetically generated images of compliant components and defective or non-compliant components can be used as a training dataset to train a machine learning system to detect compliant and non-compliant manufactured components.

### Component Count and Component Feature Count Detection

Referring now to FIG. 12, a sample image illustrates a representative component (e.g., a sheet metal plate) with hundreds of holes or features, which need to be counted using a machine learning model. In this particular example manufacturing application, a sheet-metal manufacturing machine can use a heavy duty press to punch holes into a sheet metal plate, wherein the hole-punching is one of the key steps towards completion of a final component product. In some cases, the press machine can erroneously miss out on properly punching some holes, which produces a defective component. These defects are often not identified until a later stage in the manufacturing process, which leads to operational losses.

To prevent these types of defects, the manufacturer seeks to count the number of holes on a component sheet right at the press machine and before the component sheet is dispatched to the next manufacturing stage. Counting the number of holes or other features in a manufactured component can be a difficult task, especially when the number holes or other features is of the order of hundreds or the holes or features are arranged in a non-grid or arbitrary pattern, such as the sample shown in FIG. 12.

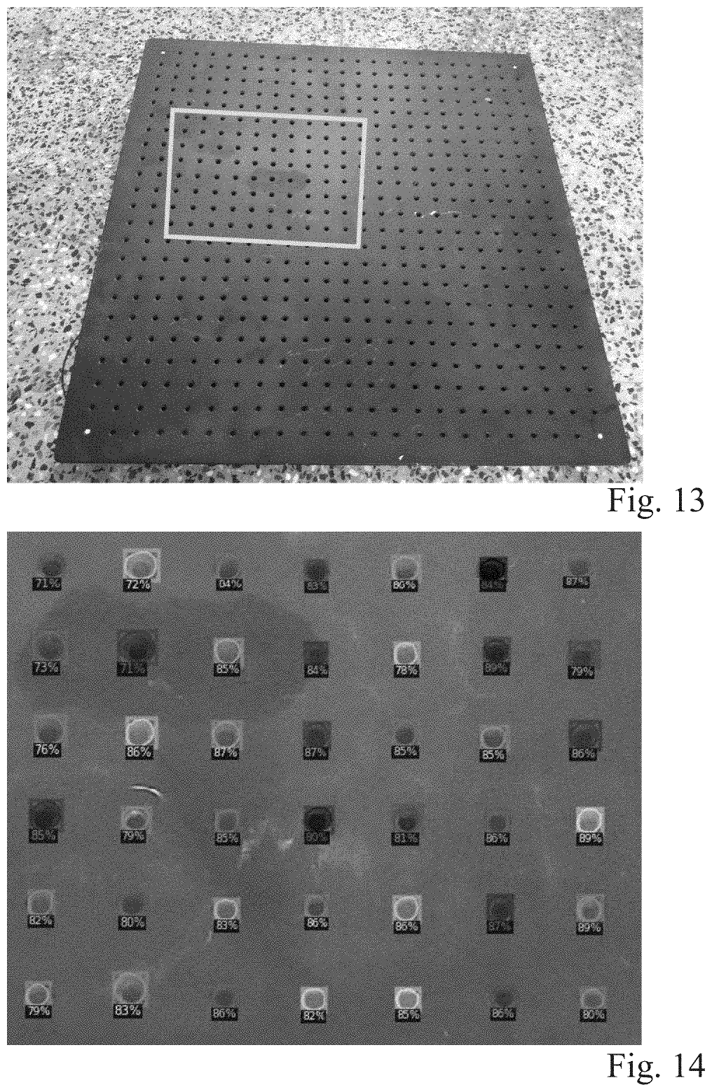

The various example embodiments described herein provide a convenient way to solve this problem by generating a synthetic representation of holes or other component features and training an object or feature detector to identify them. For example, FIGS. 13 and 14 illustrate sample images showing a representative component (e.g., a sheet metal plate) with hundreds of holes or features, which need to be counted (FIG. 13), and the results of a feature detector implemented as a machine learning model trained to identify and count holes or features of a component according to an example embodiment. In the example embodiment, images of various types of component features (e.g., holes, vias, tabs, notches, slits, protrusions, bends, etc.) and their variations can be obtained from selected images of previously manufactured components. Once the visual structure of these component features is abstracted from these selected images, the visual structure of the component features can be virtually simulated or extracted and used to synthetically generate feature images for a machine learning system training dataset. A large variety and quantity of these different images of component features can be synthetically generated in this manner. This large set of different synthetically generated images of component features can be used as a training dataset to train a machine learning system to detect and count particular features on manufactured components. It should also be noted that once a feature is detected, its size can also be estimated if the camera hardware and pose are known relative to the manufactured component. After the trained machine learning system detects and counts particular features on manufactured component, the feature count can be compared to a count corresponding to a compliant component. In this manner, the machine learning system trained with synthetically generated feature images can be used to detect defective manufactured components.

In other implementations, the example embodiments described herein provide a convenient way to also count the individual instances of the components themselves. For example, a product for shipment may contain a plurality or a set of the same component. The example embodiments described herein can generate a synthetic representation of the component and train an object or component detector to identify the individual components. In the example embodiment, images of the component and its variations can be obtained from selected images of previously manufactured components. The virtual representation of the component can also be obtained from a CAD model related to the component. Once the visual structure of the component is abstracted from these selected images, the visual structure of the component can be virtually simulated or extracted and used to synthetically generate component images for a machine learning system training dataset. A large variety and quantity of these different images of the component can be synthetically generated in this manner. This large set of different synthetically generated images of the component can be used as a training dataset to train a machine learning system to detect and count particular individual components. It should also be noted that once a component is detected, its size can also be estimated if the camera hardware and pose are known relative to the component. After the trained machine learning system detects and counts particular individual components, the component count can be compared to a count corresponding to a compliant set of components. In this manner, the machine learning system trained with synthetically generated component images can be used to detect non-compliant sets of manufactured components.

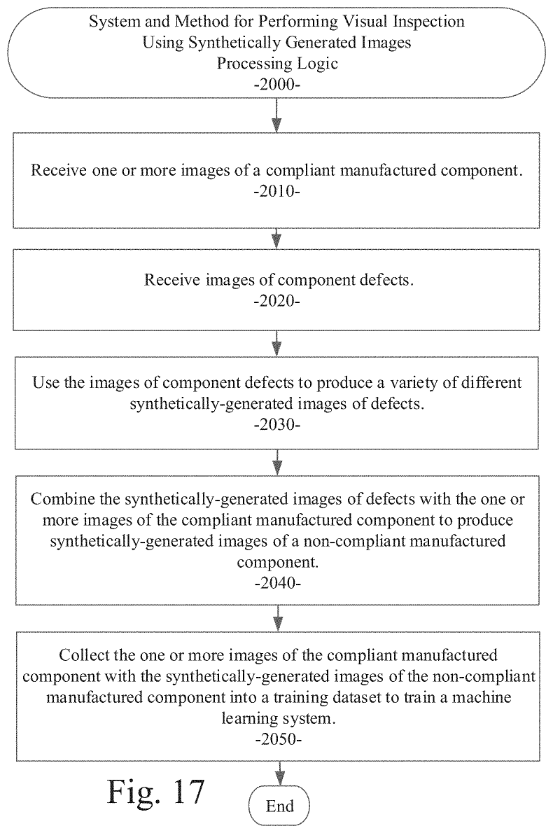

Referring now to FIG. 17, a processing flow diagram illustrates an example embodiment of a method implemented by the example embodiments as described herein. The method 2000 of an example embodiment can be configured to: receive one or more images of a compliant manufactured component (processing block 2010); receive images of component defects (processing block 2020); use the images of component defects to produce a variety of different synthetically-generated images of defects (processing block 2030); combine the synthetically-generated images of defects with the one or more images of the compliant manufactured component to produce synthetically-generated images of a non-compliant manufactured component (processing block 2040); and collect the one or more images of the compliant manufactured component with the synthetically-generated images of the non-compliant manufactured component into a training dataset to train a machine learning system (processing block 2050).

FIG. 18 shows a diagrammatic representation of a machine in the example form of a mobile computing and/or communication system 700 within which a set of instructions when executed and/or processing logic when activated may cause the machine to perform any one or more of the methodologies described and/or claimed herein. In alternative embodiments, the machine operates as a standalone device or may be connected (e.g., networked) to other machines. In a networked deployment, the machine may operate in the capacity of a server or a client machine in server-client network environment, or as a peer machine in a peer-to-peer (or distributed) network environment. The machine may be a personal computer (PC), a laptop computer, a tablet computing system, a Personal Digital Assistant (PDA), a cellular telephone, a smartphone, a web appliance, a set-top box (STB), a network router, switch or bridge, or any machine capable of executing a set of instructions (sequential or otherwise) or activating processing logic that specify actions to be taken by that machine. Further, while only a single machine is illustrated, the term “machine” can also be taken to include any collection of machines that individually or jointly execute a set (or multiple sets) of instructions or processing logic to perform any one or more of the methodologies described and/or claimed herein.

The example mobile computing and/or communication system 700 includes a data processor 702 (e.g., a System-on-a-Chip (SoC), general processing core, graphics core, and optionally other processing logic) and a memory 704, which can communicate with each other via a bus or other data transfer system 706. The mobile computing and/or communication system 700 may further include various input/output (I/O) devices and/or interfaces 710, such as a touchscreen display, an audio jack, and optionally a network interface 712. In an example embodiment, the network interface 712 can include one or more radio transceivers configured for compatibility with any one or more standard wireless and/or cellular protocols or access technologies (e.g., 2nd (2G), 2.5, 3rd (3G), 4th (4G) generation, and future generation radio access for cellular systems, Global System for Mobile communication (GSM), General Packet Radio Services (GPRS), Enhanced Data GSM Environment (EDGE), Wideband Code Division Multiple Access (WCDMA), LTE, CDMA2000, WLAN, Wireless Router (WR) mesh, and the like). Network interface 712 may also be configured for use with various other wired and/or wireless communication protocols, including TCP/IP, UDP, SIP, SMS, RTP, WAP, CDMA, TDMA, UMTS, UWB, WiFi, WiMax, Bluetooth™, IEEE 802.11x, and the like. In essence, network interface 712 may include or support virtually any wired and/or wireless communication mechanisms by which information may travel between the mobile computing and/or communication system 700 and another computing or communication system via network 714.

The memory 704 can represent a machine-readable medium on which is stored one or more sets of instructions, software, firmware, or other processing logic (e.g., logic 708) embodying any one or more of the methodologies or functions described and/or claimed herein. The logic 708, or a portion thereof, may also reside, completely or at least partially within the processor 702 during execution thereof by the mobile computing and/or communication system 700. As such, the memory 704 and the processor 702 may also constitute machine-readable media. The logic 708, or a portion thereof, may also be configured as processing logic or logic, at least a portion of which is partially implemented in hardware. The logic 708, or a portion thereof, may further be transmitted or received over a network 714 via the network interface 712. While the machine-readable medium of an example embodiment can be a single medium, the term “machine-readable medium” should be taken to include a single non-transitory medium or multiple non-transitory media (e.g., a centralized or distributed database, and/or associated caches and computing systems) that stores the one or more sets of instructions. The term “machine-readable medium” can also be taken to include any non-transitory medium that is capable of storing, encoding or carrying a set of instructions for execution by the machine and that cause the machine to perform any one or more of the methodologies of the various embodiments, or that is capable of storing, encoding or carrying data structures utilized by or associated with such a set of instructions. The term “machine-readable medium” can accordingly be taken to include, but not be limited to, solid-state memories, optical media, and magnetic media.

As described herein for various example embodiments, a system and method for performing visual inspection using synthetically generated images are disclosed. In various embodiments, a software application program is used to enable the capture and processing of images on a computing or communication system, including mobile devices. As described above, in a variety of contexts, the various example embodiments can be configured to automatically produce and use synthetic images for training a machine learning model. This collection of synthetic training images can be distributed to a variety of networked computing systems. As such, the various embodiments as described herein are necessarily rooted in computer and network technology and serve to improve these technologies when applied in the manner as presently claimed. In particular, the various embodiments described herein improve the use of mobile device technology and data network technology in the context of automated object visual inspection via electronic means.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A system comprising:
a data processor;
an image receiver in data communication with the data processor, the image receiver configured to receive one or more images of a manufactured component assembly, the image receiver also configured to receive one or more images of sub-components of the component assembly; and
a synthetic training data generation system executable by the data processor, the synthetic training data generation system configured to:
virtually assemble models for different sub-components of the component assembly;
render the sub-component models into images of various component assembly variants; and
collect the images of the various component assembly variants into a training dataset to train a machine learning system.

2. The system of claim 1 wherein the synthetic training data generation system being further configured to render the sub-component models into images of various component assembly variants with different backgrounds.

3. The system of claim 1 wherein the synthetic training data generation system being further configured to render the sub-component models into images of various component assembly variants with different orientations.

4. A method comprising:
receiving one or more images of a manufactured component assembly;
receiving one or more images of sub-components of the component assembly;
virtually assembling models for different sub-components of the component assembly;
rendering the sub-component models into images of various component assembly variants; and
collecting the images of the various component assembly variants into a training dataset to train a machine learning system.

5. The method of claim 4 including rendering the sub-component models into images of various component assembly variants with different backgrounds.

6. The method of claim 4 including rendering the sub-component models into images of various component assembly variants with different orientations.

7. A system comprising:
a data processor;
an image receiver in data communication with the data processor, the image receiver configured to receive one or more images of a compliant manufactured component, the image receiver also configured to receive images of component defects; and
a synthetic training data generation system executable by the data processor, the synthetic training data generation system configured to:
use the images of component defects to produce a variety of different synthetically-generated images of defects;
combine the synthetically-generated images of defects with the one or more images of the compliant manufactured component to produce synthetically-generated images of a non-compliant manufactured component; and
collect the one or more images of the compliant manufactured component with the synthetically-generated images of the non-compliant manufactured component into a training dataset to train a machine learning system.

8. The system of claim 7 wherein the synthetic training data generation system being further configured to produce the variety of different synthetically-generated images of defects by re-sizing, rotating, re-locating, or multiplying the images of component defects.

9. The system of claim 7 wherein the synthetic training data generation system being further configured to generate a three-dimensional (3D) virtual model of the compliant manufactured component.

10. The system of claim 7 wherein the synthetic training data generation system being further configured to generate a three-dimensional (3D) virtual model of the compliant manufactured component with a desired structure and surface texture in a variety of different lighting conditions, various camera settings or angles, and different virtual backgrounds.

11. A method comprising:
receiving one or more images of a compliant manufactured component;
receiving images of component defects;
using the images of component defects to produce a variety of different synthetically-generated images of defects;
combining the synthetically-generated images of defects with the one or more images of the compliant manufactured component to produce synthetically-generated images of a non-compliant manufactured component; and
collecting the one or more images of the compliant manufactured component with the synthetically-generated images of the non-compliant manufactured component into a training dataset to train a machine learning system.

12. The method of claim 11 including producing the variety of different synthetically-generated images of defects by re-sizing, rotating, re-locating, or multiplying the images of component defects.

13. The method of claim 11 including generating a three-dimensional (3D) virtual model of the compliant manufactured component.

14. The method of claim 11 including generating a three-dimensional (3D) virtual model of the compliant manufactured component with a desired structure and surface texture in a variety of different lighting conditions, various camera settings or angles, and different virtual backgrounds.

15. A system comprising:
a data processor;
an image receiver in data communication with the data processor, the image receiver configured to receive one or more images of features of a manufactured component; and
a synthetic training data generation system executable by the data processor, the synthetic training data generation system configured to:
use the images of component features to produce a variety of different synthetically-generated images of component features;
collect the different synthetically-generated images of component features into a training dataset to train a machine learning system.

16. The system of claim 15 wherein the synthetic training data generation system being further configured to produce the variety of different synthetically-generated images of component features by re-sizing, rotating, re-locating, or multiplying the images of component features.

17. The system of claim 15 wherein the machine learning system being configured to count a quantity of manufactured components or component features on the manufactured component.

18. A method comprising:
receiving one or more images of features of a manufactured component;
using the images of component features to produce a variety of different synthetically-generated images of component features; and
collecting the different synthetically-generated images of component features into a training dataset to train a machine learning system.

19. The method of claim 18 including producing the variety of different synthetically-generated images of component features by re-sizing, rotating, re-locating, or multiplying the images of component features.

20. The method of claim 18 wherein the machine learning system being configured to count a quantity of manufactured components or component features on the manufactured component.
